(19) United States
(12) Patent Application Publication
(10) Pub. No.: US 2008/0224159 A1
(43) Pub. Date: Sep. 18, 2008

(54) Optical Element, Optoelectronic Component Comprising Said Element, and the Production Thereof

(76) Inventors: Gertrud Krauter, Regensburg (DE); Andreas Plossl, Regensburg (DE)

Correspondence Address: NEXSEN PRUET, LLC, P.O. BOX 10648, GREENVILLE, SC, 29603, US

(21) Appl. No.: 11/912,831

(22) PCT Filed: Apr. 18, 2006
(86) PCT No.: PCT/DE06/00673

§ 371 Date: Apr. 2, 2008

(30) Foreign Application Priority Data
Apr. 26, 2005 (DE) 10 2005 019 374.9
Aug. 3, 2005 (DE) 10 2005 036 520.5

(51) Int. Cl. H01L 33/00; C08G 73/00; C08G 63/02; C08G 64/00; C08G 65/00; C08G 2/08; C08F 236/06; C08F 120/18; C08F 110/06; C08F 110/02; C08F 212/08; C08G 71/04; C08F 220/44; B29C 45/00; H01J 37/30

(52) U.S. Cl. 257/98; 528/422; 528/272; 528/425; 528/86; 528/270; 526/338; 526/329.7; 526/351; 526/352; 526/347; 528/44; 526/346; 526/342; 428/336; 264/328.1; 264/485; 257/E33.068; 257/E33.059

(57) ABSTRACT

The invention relates to an optical element (1, 25) having a defined shape and comprising a thermoplastic material that has been further cross-linked during or following the shaping thereof. Such thermoplastic materials have an increased heat deflection temperature, distortion, but can be easily and economically shaped before the additional cross-linking as a result of the thermoplastic properties thereof.

### FIELD OF THE INVENTION

This invention relates to the formation of optical crosslinked polymers which become crosslinked during or after shaping.

### BACKGROUND AND PRIOR ART

In the case of potting materials for optoelectronic components, such as for example radial LEDs, smart LEDs or chip LEDs, package materials for optoelectronic components such as SMD LEDs or also optical elements such as for example lenses, it is often necessary that the respective materials be stable during soldering. For this reason, high-temperature plastics filled with glass fibers and/or with minerals are used today, which materials are very expensive and can be processed only at high temperatures by special injection molding methods. Thermoset plastics such as epoxy polymers or silicones can be used for encapsulations or optical elements of optoelectronic components. These plastics, however, can be shaped only with difficulty.

It is therefore an object of the invention to identify an optical element that reduces the above-cited disadvantages.

### BRIEF DESCRIPTION OF THE INVENTION

According to the invention, this object is achieved with an optical element which is crosslinked during or after being shaped. Further advantageous embodiments of the optical element as well as an optoelectronic component having the element and its fabrication are the subject of further claims.

The subject of the invention is an optical element having a definite shape, comprising a thermoplastic that was crosslinked during or after shaping.

The advantage of an optical element according to the invention is that it is possible to employ a standard thermoplastic, which by virtue of its thermoplastic properties exhibits a flow transition range above its service temperature and thus, in the softened condition, can be shaped into an optical element in a particularly simple fashion, for example by compression, extrusion, injection molding or injection stamping and other shaping methods. The thermoplastic is then not crosslinked until during or after shaping, the result being a modified thermoplastic that exhibits an elevated heat deflection temperature, a lower coefficient of thermal expansion and improved mechanical properties. Surprisingly, the inventors found that despite crosslinking being performed during or after shaping, optical elements made from these crosslinked thermoplastics exhibit, just as in the prior art, optical properties good enough that the elements can also be employed in optoelectronic systems. The optical elements according to the invention, which comprise the additionally crosslinked thermoplastics, are also surprisingly stable against soldering, so that optoelectronic components that exhibit these elements can be mounted in conventional fashion by soldering to substrates, for example printed circuit boards.

### BRIEF DESCRIPTION OF THE DRAWINGS

FIG. 1 is a cross-section of a radiation emitting component.

FIG. 2 is a cross-section of a radiation emitting component with a lens affixed.

FIG. 3 is a cross-section of a radiation emitting component having a lens affixed by feet.

FIG. 4 is a cross-section of a radiation emitting component anchored to a substrate using feet.

FIG. 5 is a cross-section of a radiation emitting component with an inorganic coating on its lens and affixed to a substrate using solder.

FIG. 6 depicts a radiation emitting component wherein the lens is attached to the package by fastening elements.

FIGS. 7A and 7B are perspective views of a lens having peripheral fastening elements and centering lugs.

FIG. 7C is a cross-section of the lens of FIGS. 7A and 7B.

### DETAILED DESCRIPTION OF THE INVENTION

Optical elements according to the invention can exhibit arbitrary shapes depending on application. Thus for example they can be shaped as packages for the radiation-emitting semiconductor chips, as reflectors or as lenses. The optical elements can thus be given any shape usable for optoelectronic applications. By virtue of the thermoplastic properties, shaping, for example by injection molding, can be carried out in particularly simple fashion, crosslinking not taking place until during or after shaping.

In a further embodiment of the invention, the expression optical element means an element that interacts with light, that is, in particular, is light-shaping, light-conveying and/or light-transforming. Examples of optical elements are for example lenses that can condense light as well as reflectors that reflect light.

In an embodiment of the invention it is possible that the thermoplastic is crosslinked by irradiation after shaping. Such irradiation for crosslinking the thermoplastic can be effected for example by irradiation with beta rays or gamma rays. Such irradiations can take place for example in conventional electron accelerators and gamma emitting devices. Among the effects of irradiation is the generation of free radicals in the easily processable thermoplastics, which free radicals, by virtue of their reactivity, bring about further crosslinking of the thermoplastic polymer strands so that highly crosslinked three-dimensional polymer networks can come about.

In another embodiment of the invention it is possible that additional crosslinking takes place under high pressure during shaping, for example during extruding, as a result of the addition of crosslinking agents. Such crosslinking agents can for example comprise organic peroxides, which likewise are capable of enabling three-dimensional crosslinking of thermoplastics via chemical routes. Here a uniform network of thermoplastic macromolecules can come about.

Crosslinking aids can also be employed in the case of the above-mentioned radiation crosslinking in order to shorten irradiation times and diminish byproducts of radiation, for example by fragmentation or oxidation.

According to the invention, crosslinking taking place during or after the shaping of the optical element makes it possible to employ all heretofore unusable low-priced industrial thermoplastics that are for example processable at moderate temperatures by injection molding. The thermoplastics used in optical elements according to the invention can be selected from a group that contains the following plastics: polyamide, polyamide 6, polyamide 6,6, polyamide 6,12, polybutylene terephthalate, polyethylene terephthalate, polycarbonate, polyphenylene oxide, polyoxymethylene, acrylonitrile-butadiene-styrene copolymer, polymethyl methacrylate, modified polypropylene, ultrahigh-molecular-weight polyethylene, ethylene-styrene interpolymers, copolyester elastomers, thermoplastic urethane, polymethyl methacrylimide, cycloolefin copolymers, cycloolefin polymers, polystyrene and styrene-acrylonitrile copolymer.

The plastics named can in each case be employed alone or in arbitrary combinations for the fabrication of optical elements according to the invention.

The changes in properties occurring upon the subsequent crosslinking of thermoplastics can be demonstrated through a variety of thermal, physical and mechanical tests. In this way it is possible to distinguish conventional non-crosslinked thermoplastics from crosslinked thermoplastics. Thus for example the incorporation of oxygen-containing groups at the surface of radiation-crosslinked thermoplastics can be detected by infrared spectroscopy. Electron bombardment causes among other things a rise in the interfacial tension of radiation-crosslinked thermoplastic materials, so that the polarity of the thermoplastic surface is increased.

The increase in the glass transition temperature of additionally crosslinked thermoplastics can be demonstrated for example by dilatometric, dielectric, dynamic-mechanical or refractometric measurements, by DSC (differential scanning calorimetry) or with the aid of NMR spectroscopy, all of which are known to an individual skilled in the art.

DMA torsion tests likewise give direct information about the glass transition temperature T_{g}, the altered melting and crystallization properties and the heat deflection temperature of crosslinked thermoplastics. Near the glass transition range, up to the melting range, crosslinked thermoplastic materials are often stiffer than non-crosslinked thermoplastic materials, with the consequence that crosslinked thermoplastics no longer flow, so that the heat deflection temperature is improved. Crosslinked thermoplastics often exhibit rubber-type elasticity in the melting range and no longer flow. Crosslinking further reduces the thermal expansion as well as the permeability to water and oxygen. Silver migration is likewise limited.

Optical elements according to the invention advantageously comprise a thermoplastic that is substantially transparent to radiation. The radiation here can be from all possible radiation sources, for example optoelectronic components into which the optical element is integrated. The expression substantially transparent here means that the thermoplastic exhibits a transparency of some 70 to 80%, preferably up to 92%, for the radiation. Surprisingly, the inventors found that cross-linked thermoplastic plastics, just as before, exhibit sufficiently transparent properties.

Further, an inorganic coating can be disposed on an optical element according to the invention. This can enhance the mechanical stability, stability against soldering and resistance to water penetration in addition to crosslinking. This inorganic coating can for example comprise materials that are selected from silicon dioxide and titanium dioxide. The coating here can comprise just one of the materials or a combination of both materials. Such coatings can for example be applied in a deposition process from the gas phase with coating thicknesses of some 50 nm to 1000 nm. Coatings with such coating thicknesses are additionally also transparent to radiation to the greatest degree.

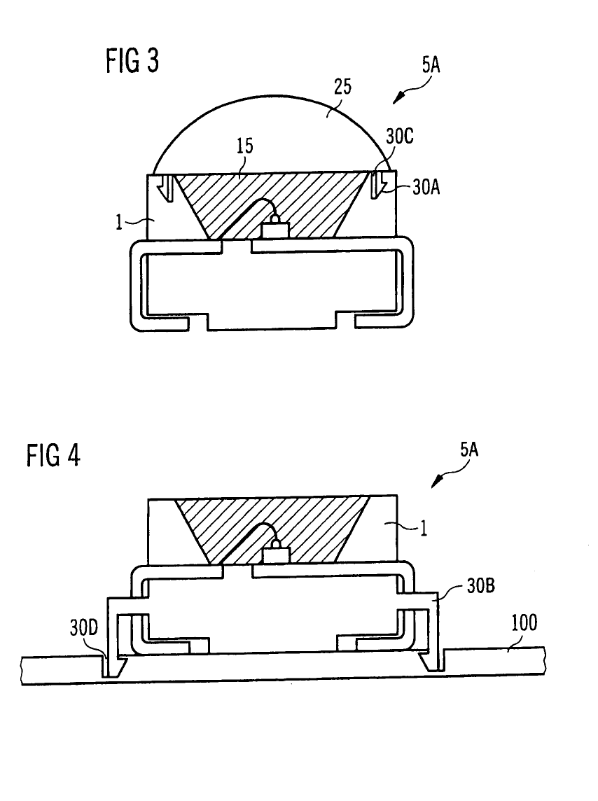

In a further embodiment, connecting elements can be shaped from the thermoplastic material of an optical element according to the invention (see for example FIGS. 3 and 4). Such connecting elements can for example serve to connect optical elements with optoelectronic radiation-emitting components. Optoelectronic elements having these optical elements can then also be mounted in particularly simple fashion on a substrate, for example a printed circuit board, via further connecting elements made of the crosslinked thermoplastics (see for example FIG. 4). The connecting elements, for example lugs, tabs, plugs or the like, can be shaped in particularly simple fashion from thermoplastic materials because these are readily meltable and therefore easily shaped. The thermoplastic materials of an optical element according to the invention are not further crosslinked until after or during the shaping of these connecting elements, so that enhanced stability results.

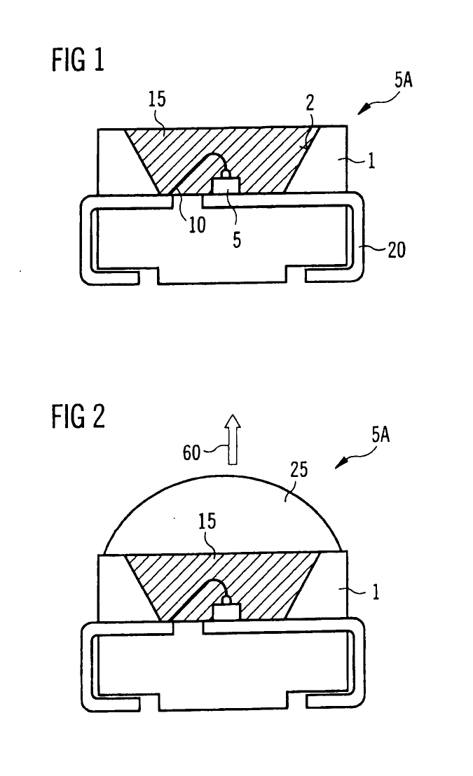

Optical elements according to the invention can here comprise a lens or a reflector (see for example FIGS. 1 to 5). In the case of a lens, this can be cemented to an existing potting of an optoelectronic component, this component then being stable against soldering despite the thermoplastic (see for example FIG. 2). In the case of a reflector as optical element, the thermoplastic plastic employed is preferably one that exhibits a high reflectivity and is not transparent. Further additives, for example titanium dioxide (white pigment), are often added to the thermoplastic in this case. It is also possible to shape packages, which simultaneously also exhibit reflector properties, from subsequently crosslinked thermoplastic material (see for example FIGS. 1 and 2).

A further subject of the invention is an optoelectronic radiation-emitting component having an optical element comprising a crosslinked thermoplastic. Such elements often exhibit good optical properties similar to those of elements made of special high-temperature plastics heretofore used, but they are simpler and cheaper to fabricate.

It is particularly advantageous if the optical element is shaped as a package, because in this way it is possible to ensure particularly good stability of a radiation-emitting component against soldering. By virtue of its good optical properties, for example its good transparency, the optical element can also be disposed in the beam path of the component and is then substantially transparent to the emitted radiation (see for example FIG. 2).

Because of the increased temperature stability and improved properties of crosslinked thermoplastic materials, it is particularly favorable to use this material to fasten a radiation-emitting component to a substrate. This can be effected for example with locking elements or by soldering methods (see for example FIGS. 4 and 5).

A further subject of the invention is a method for fabricating an optical element of a definite shape comprising the procedural steps:
A) preparing a thermoplastic,
B) converting the thermoplastic to the desired shape,
C) crosslinking the thermoplastic, the optical element being formed.

An injection molding method is advantageously employed in procedural step B). Additionally, before procedural step C), a crosslinking aid is frequently added, for example triallyl isocyanurate (TAIC), which facilitates crosslinking.

In the case of chemical crosslinking methods it is possible for example to carry out procedural steps B) and C) together, using chemical crosslinkers such as for example organic peroxides.

In the case of radiation crosslinkings, in procedural step C), the shaped thermoplastic can be exposed to a radiation dose of some 30 to 400 kGy, preferably 33 to 165 kGy, with electron beams.

In what follows, the invention will be explained in greater detail with reference to the Drawings and exemplary embodiments.

### EXEMPLARY EMBODIMENTS

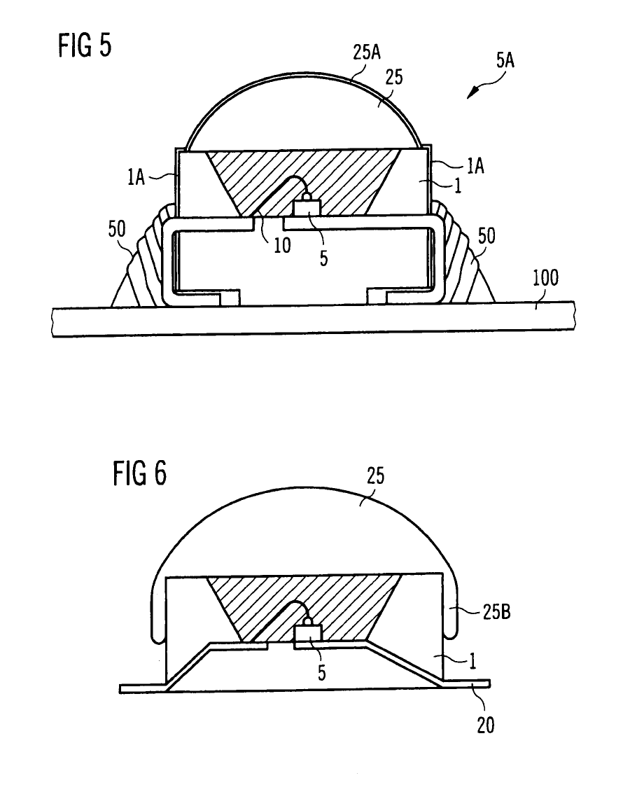

Lenses 2-3 mm thick having a diameter of 0.8 cm were injection molded from a polyamide (Grilamid TR 90), triallyl isocyanurate (TAIC, Perkalink 301) in liquid form being added to the plastic granulate as a crosslinking aid. The content of TAIC added was 2-5% by weight, preferably some 3 to 4% by weight. The addition took place either directly as the liquid or adsorbed on a porous granulate. Calcium silicate was not employed as a support for TAIC, as it otherwise usually is, because it has a detrimental effect on the transparency of the lenses. Crosslinking was then brought about by irradiation with beta rays for some seconds, with a typical dose of 66-132 kGy. Irradiation takes place sequentially in 33 kGy steps. Irradiation is performed at least twice, but preferably four times, for example with the same radiation dose each time. The lenses can exhibit connecting elements in the form of feet for anchoring (see for example FIGS. 3 and 6).

If injection molding is carried out with an inert-gas-purged granulate, for example an N₂-purged granulate, in an injection molding machine purged with N₂, glass-clear products are obtained. Radiation crosslinking leads to the formation of color centers, which cause a yellow coloration of the injection moldings. This discoloration disappears completely upon soldering at 260° C. The soldered products are glass-clear with a transparency of 85-90%. In place of N₂, other inert gases can also be employed, the inventors having established that when inert gases are employed as described above, the discoloration that occurs during radiation crosslinking is then reduced or disappears completely upon soldering. It is particularly advantageous also to work under an inert gas, for example N₂, during radiation crosslinking. This can be done by packing the optical elements in plastic bags under inert gas and then crosslinking them.

Lenses made from radiation-crosslinked Grilamid TR 90, in contrast to lenses made of the non-crosslinked material, were stable against soldering and exhibited a transparency of some 70-95%, preferably 85-90%. Furthermore, water absorption by the lenses made of the crosslinked material was reduced so much that no bubble formation was observed upon soldering at a maximum temperature of 260° C. for 30 s.

Analogously to the above-cited radiation crosslinking of lenses, LED packages comprising thermoplastics filled with white pigment can also be fabricated, for example by injection molding methods, and radiation-crosslinked, the resulting package then being stable against soldering, in contrast to packages not radiation-crosslinked. Along with the top LEDs depicted in FIGS. 1-6 and known to an individual skilled in the art, packages of so-called smart LEDs and chip LEDs, likewise known to an individual skilled in the art, can be radiation-crosslinked in this way. Smart LEDs are described for example in the publication DE 199 63 806 C2, to which reference is hereby made, and exhibit an LED having a leadframe, which is encapsulated with a plastic molding compound in such fashion that the LED is surrounded by the molding compound on its light exit sides. The plastic molding compound can also be admixed with a light conversion substance. In the case of chip LEDs, LEDs are mounted on a printed circuit board that exhibits contacts for mounting and encapsulated with a plastic molding compound.

FIGS. 1 to 7 depict various embodiments of radiation-emitting components according to the invention having optical elements made of crosslinked thermoplastic materials, in cross section, as well as a radiation-crosslinked lens that is suitable for incorporation in an optoelectronic component.

FIG. 1 depicts in cross section a radiation-emitting component 5A wherein a semiconductor component 5, for example an LED, is electrically contacted by a bond wire 10 and a conductor band 20. Semiconductor component 5 is situated in a reflector dish that exhibits a reflector surface 2 and condenses the light emitted by the semiconductor component. The reflector dish and semiconductor component 5 situated therein are enveloped by a potting 15 comprising for example epoxy or silicone. Radiation-emitting component 5A exhibits a package 1 made of a radiation-crosslinked or chemically crosslinked thermoplastic that exhibits high reflectivity, from which reflector surfaces 2 of the reflector dish are simultaneously shaped. In contrast to conventional radiation-emitting components, wherein package 1 is made up either of expensive high-temperature plastics or of thermoset plastics, radiation-emitting components according to the invention can be fabricated more cheaply and easily on account of the easy shapability of thermoplastics.

A cross section of a further embodiment of a radiation-emitting component 5A according to the invention is illustrated in FIG. 2. Here, in contrast to the component of FIG. 1, there is additionally a lens 25 that is affixed to potting 15 of the component. Such a lens 25 can also be shaped in particularly simple fashion from a subsequently crosslinked thermoplastic material. Depending on what requirements apply to the component, package 1 of the component of FIG. 2 can also comprise a subsequently crosslinked thermoplastic material or can also comprise conventional high-temperature thermoplastics or thermoset plastics. Because, surprisingly, it is also possible to fabricate subsequently crosslinked thermoplastic materials having sufficiently transparent properties, it is immediately possible to dispose lens 25 fabricated from the subsequently crosslinked thermoplastic material in beam path 60 of component 5A.

FIG. 3 depicts a further variant of a radiation-emitting component 5A according to the invention, wherein a lens 25 is disposed on potting 15, which lens likewise comprises subsequently radiation-crosslinked thermoplastic material and additionally exhibits connecting elements 30A. In this case connecting elements 30A comprise small feet that permit the feet to be mechanically anchored by a snap mechanism in recesses 30C of package 1. In such an exemplary embodiment it is no longer necessary, as otherwise it usually is, to fasten lens 25 to potting 15 of component 5A, for example by cementing.

Alternatively or additionally to the exemplary embodiment of FIG. 3, FIG. 4 shows that connecting elements 30B can also be shaped in package 1, which according to the invention comprises additionally crosslinked thermoplastic materials, which connecting elements make it possible to anchor component 5A on a substrate 100, for example a printed circuit board, in particularly simple fashion. In this case again, connecting elements 30B in the form of feet are fastened in recesses 30D of substrate 100 by a snap mechanism. Such fastening methods can for example replace conventional soldering methods and thus diminish or prevent thermal stress on the component.

Because of the additional heat deflection temperature of additionally crosslinked thermoplastic materials, radiation-emitting components exhibiting packages 1 made of these materials can also be fastened to substrates 100 by soldering methods without major problems.

FIG. 5 depicts in cross section a further exemplary embodiment of the invention wherein both lens 25 and also package 1 comprise subsequently crosslinked thermoplastic materials. In order to increase the stability against soldering still further, enhance the barrier properties for water and impart greater mechanical stability, an inorganic coating 25A can be disposed on lens 25 and an inorganic coating 1A can be disposed on package 1. Such coatings, which for example can contain materials that are selected from silicon dioxide and titanium dioxide, can for example be applied in coating thicknesses of 50 nm to 1000 nm by deposition processes from the gas phase. The component here is mounted on substrate 100 by soldering with solder 50.

FIG. 6 depicts a component wherein lens 25 is stuck onto package 1 via fastening elements 25B. In contrast to the component depicted in FIG. 3, fastening elements 25B surround package 1.

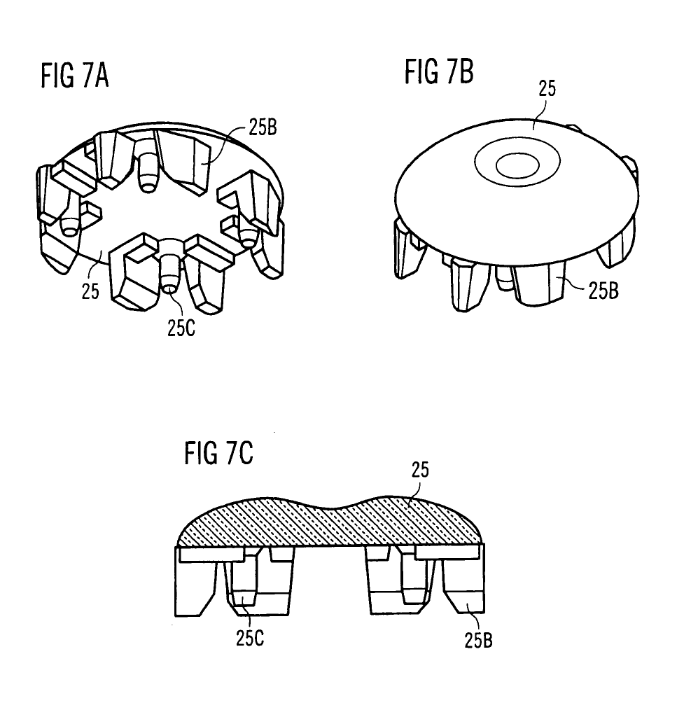

FIG. 7 depicts in FIGS. 7A and 7B perspective views of a possible exemplary embodiment of a lens 25 that can be stuck onto a package 1 similarly to what is depicted in FIG. 6. In addition to fastening elements 25B there are also lugs 25C, which are stuck into corresponding recesses in the package. FIG. 7C depicts lens 25 in cross section.

The invention described here is not limited to the exemplary embodiments presented. Instead, the invention comprises every novel feature as well as every combination of features, which contains in particular every combination of features in the claims, even if this feature or this combination proper is not explicitly identified in the claims or the exemplary embodiments. Further variations are possible above all in relation to the thermoplastic materials employed as well as the shape and function of the optical elements shaped from these subsequently crosslinked thermoplastic materials.

1. An optical element (1, 25) having a definite shape, comprising a thermoplastic that was crosslinked during or after shaping.

2. The optical element (1, 25) according to claim 1, wherein the thermoplastic was crosslinked by irradiation after shaping.

3. The optical element (1, 25) according to claim 1, wherein crosslinking was effected by the addition of crosslinking agents during shaping.

4. The optical element (1, 25) according to claim 1, wherein the thermoplastic is selected from a group constisting of: polyamide (PA), polyamide 6 (PA 6); polyamide 6,6 (PA 6,6), polyamide 6,12 (PA 6,12); polybutylene terephthalate (PBT); polyethylene terephthalate (PET); polycarbonate (PC); polyphenylene oxide (PPO); polyoxymethylene (POM); acrylonitrile-butadiene-styrene copolymer (ABS); polymethyl methacrylate (PMMA); modified polypropylene (PP-modified); ultrahigh-molecular-weight polyethylene (PE-UHMW), ethylene-styrene interpolymers (ESI); copolyester elastomers (COPE); thermoplastic urethane (TPU); polymethyl methacrylimide (PMMI); cycloolefin copolymers (COC); cycloolefin polymers (COP), polystyrene (PS) and styrene-acrylonitrile copolymer (SAN).

5. The optical element (1, 25) according to claim 1, wherein the thermoplastic is substantially transparent to radiation.

6. The optical element (1, 25) according to claim 1, on which an inorganic coating (1A, 25A) is additionally applied.

7. The optical element (1, 25) according to claim 6, wherein the inorganic coating (1A, 25A) comprises materials that are selected from the group consisting of SiO₂ and TiO₂.

8. The optical element (1, 25) according to claim 7, wherein the coating exhibits a coating thickness of 50 nm to 1000 nm.

9. The optical element (1, 25) according to claim 1, wherein connecting elements (30A, 30B) are additionally shaped from the thermoplastic.

10. The optical element (25) according to claims 1, which is a lens.

11. The optical element (1) according to claims 1, which is a reflector.

12. An optoelectronic radiation-emitting component (5A) having an optical element (1, 25) according to claim 1.

13. The radiation-emitting component (5A) according to claim 12, the optical element (1, 25) being shaped as package.

14. The radiation-emitting component (5A) according to claim 13, wherein the optical element (1, 25) is disposed in the beam path (60) of the component (5A) and is substantially transparent to the radiation emitted.

15. The radiation-emitting component according to claim 14, wherein the entire component is encapsulated by the package.

16. A disposition of a radiation-emitting component (5A) according to claim 12 on a substrate (100), the component (5A) being fastened to the substrate (100) via the optical element (1, 25).

17. The disposition according to claim 16, wherein the component (5A) is fastened to the substrate (100) by soldering.

18. A method for fabricating an optical element (1, 25) of a definite shape, having the procedural step comprising:
A) preparing a thermoplastic,
B) converting the thermoplastic to the desired shape and
C) crosslinking the thermoplastic, the optical element being formed.

19. The method according to claim 18, wherein an injection molding method is employed in procedural step B).

20. The method according to claim 18, wherein additionally, before procedural step C), a crosslinking aid is added.

21. The method according to claim 18, wherein after procedural step B) in procedural step C), the shaped thermoplastic is exposed to a radiation dose of some 33 to 165 kGy with electron beams.

22. The method according to claim 18, wherein procedural steps B) and C) are carried out together.

23. The method according to claim 18, wherein a transparent thermoplastic is employed.

24. The method according to claim 18, wherein in procedural step B) the conversion of the thermoplastic into the desired shape is carried out under inert gas.

25. The method according to claim 18, wherein procedural step C) is carried out under inert gas.

26. The method according to claim 18, wherein in procedural step C) the shaped thermoplastic is crosslinked at least twice by radiation.

27. Use, for optoelectronic components, of elements having a definite shape and comprising a thermoplastic that was crosslinked during or after shaping.
